(19) United States
(12) Patent Application Publication
(10) Pub. No.: US 2022/0360246 A1
(43) Pub. Date: Nov. 10, 2022

(54) TRANSVERSELY-EXCITED FILM BULK ACOUSTIC RESONATOR FABRICATION USING A PIEZOELECTRIC PLATE, SILICON SUBSTRATE AND HANDLE WAFER SANDWICH

(71) Applicant: Resonant Inc., Austin, TX (US)

(72) Inventors: Kuan Zhang, Goleta, CA (US); Andrew Kay, Provo, UT (US); Albert Cardona, Santa Barbara, CA (US); Chris O'Brien, San Diego, CA (US)

(21) Appl. No.: 17/565,271

(22) Filed: Dec. 29, 2021

Related U.S. Application Data
(63) Continuation of application No. 17/565,123, filed on Dec. 29, 2021.
(60) Provisional application No. 63/185,465, filed on May 7, 2021.

(51) Int. Cl. H03H 9/02; H03H 3/04; H03H 9/13; H03H 9/17

(52) U.S. Cl. CPC H03H 9/02228; H03H 3/04; H03H 9/02102; H03H 9/02133; H03H 9/13; H03H 9/174; H03H 2003/023

(57) ABSTRACT

An acoustic resonator device is formed that reduces a thermal coefficient of expansion mismatch between a piezoelectric plate and a silicon substrate by bonding the front surface of the silicon substrate having a filled and planarized sacrificial tub to a piezoelectric substrate and thinning the silicon substrate by removing material from a back surface. That back surface is then bonded to a handle wafer having a thermal coefficient of expansion (TCE) closer to a TCE of the piezoelectric substrate than a TCE of the silicon substrate and thinning the piezoelectric substrate to a target piezoelectric membrane thickness to form a piezoelectric plate. A conductor pattern is formed on the thinned piezoelectric plate and the sacrificial tub is removed to form a cavity and release a membrane of the piezoelectric plate using an etchant introduced through holes in the piezoelectric plate.

### RELATED APPLICATION INFORMATION

This patent is a continuation of co-pending U.S. application Ser. No. 17/565,123, titled TRANSVERSELY-EXCITED FILM BULK ACOUSTIC RESONATOR FABRICATION USING A PIEZOELECTRIC PLATE, SILICON SUBSTRATE AND HANDLE WAFER SANDWICH, filed Dec. 29, 2021 which claims priority to co-pending U.S. provisional patent application No. 63/185,465, titled METHOD FOR XBAR FABRICATION USING LN-SILICON-LN LAMINATE, filed May 7, 2021, all of which are incorporated herein by reference.

A portion of the disclosure of this patent document contains material which is subject to copyright protection. This patent document may show and/or describe matter which is or may become trade dress of the owner. The copyright and trade dress owner has no objection to the facsimile reproduction by anyone of the patent disclosure as it appears in the Patent and Trademark Office patent files or records, but otherwise reserves all copyright and trade dress rights whatsoever.

### BACKGROUND

### Field

This disclosure relates to radio frequency filters using acoustic wave resonators, and specifically to filters for use in communications equipment.

### Description of the Related Art

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “pass-band” of the filter. The range of frequencies stopped by such a filter is referred to as the “stop-band” of the filter. A typical RF filter has at least one pass-band and at least one stop-band. Specific requirements on a passband or stop-band depend on the specific application. For example, a “pass-band” may be defined as a frequency range where the insertion loss of a filter is better than a defined value such as 1 dB, 2 dB, or 3 dB. A “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front-ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

RF filters typically require many design trade-offs to achieve, for each specific application, the best compromise between performance parameters such as insertion loss, rejection, isolation, power handling, linearity, size and cost. Specific design and manufacturing methods and enhancements can benefit simultaneously one or several of these requirements.

Performance enhancements to the RF filters in a wireless system can have broad impact to system performance. Improvements in RF filters can be leveraged to provide system performance improvements such as larger cell size, longer battery life, higher data rates, greater network capacity, lower cost, enhanced security, higher reliability, etc. These improvements can be realized at many levels of the wireless system both separately and in combination, for example at the RF module, RF transceiver, mobile or fixed sub-system, or network levels.

High performance RF filters for present communication systems commonly incorporate acoustic wave resonators including surface acoustic wave (SAW) resonators, bulk acoustic wave (BAW) resonators, film bulk acoustic wave resonators (FBAR), and other types of acoustic resonators. However, these existing technologies are not well-suited for use at the higher frequencies and bandwidths proposed for future communications networks.

The desire for wider communication channel bandwidths will inevitably lead to the use of higher frequency communications bands. Radio access technology for mobile telephone networks has been standardized by the 3GPP (3^{rd} Generation Partnership Project). Radio access technology for 5^{th} generation mobile networks is defined in the 5G NR (new radio) standard. The 5G NR standard defines several new communications bands. Two of these new communications bands are n77, which uses the frequency range from 1300 MHz to 4200 MHz, and n79, which uses the frequency range from 4400 MHz to 5000 MHz. Both band n77 and band n79 use time-division duplexing (TDD), such that a communications device operating in band n77 and/or band n79 use the same frequencies for both uplink and downlink transmissions. Bandpass filters for bands n77 and n79 must be capable of handling the transmit power of the communications device. WiFi bands at 5 GHz and 6 GHz also require high frequency and wide bandwidth. The 5G NR standard also defines millimeter wave communication bands with frequencies between 24.25 GHz and 40 GHz.

The Transversely-Excited Film Bulk Acoustic Resonator (XBAR) is an acoustic resonator structure for use in microwave filters. The XBAR is described in U.S. Pat. No. 10,491,291, titled TRANSVERSELY EXCITED FILM BULK ACOUSTIC RESONATOR. An XBAR resonator comprises an interdigital transducer (IDT) formed on a thin floating layer, or diaphragm, of a single-crystal piezoelectric material. The IDT includes a first set of parallel fingers, extending from a first busbar and a second set of parallel fingers extending from a second busbar. The first and second sets of parallel fingers are interleaved. A microwave signal applied to the IDT excites a shear primary acoustic wave in the piezoelectric diaphragm. XBAR resonators provide very high electromechanical coupling and high frequency capability. XBAR resonators may be used in a variety of RF filters including band-reject filters, band-pass filters, duplexers, and multiplexers. XBARs are well suited for use in filters for communications bands with frequencies above 3 GHz.

### DESCRIPTION OF THE DRAWINGS

FIG. 1 includes a schematic plan view and two schematic cross-sectional views of a transversely-excited film bulk acoustic resonator (XBAR).

FIG. 2 is an expanded schematic cross-sectional view of a portion of the XBAR of FIG. 1.

FIG. 3A is an alternative schematic cross-sectional view of an XBAR.

FIG. 3B is a graphical illustration of the primary acoustic mode of interest in an XBAR.

FIG. 3C is a schematic circuit diagram and layout for a high frequency band-pass filter using XBARs.

FIGS. 4A, 4B and 4C (collectively “FIG. 4”) are a flow chart of a process for fabricating an XBAR using a piezoelectric plate, silicon substrate and handle wafer sandwich.

Throughout this description, elements appearing in figures are assigned three-digit or four-digit reference designators, where the two least significant digits are specific to the element and the one or two most significant digit is the figure number where the element is first introduced. An element that is not described in conjunction with a figure may be presumed to have the same characteristics and function as a previously-described element having the same reference designator or the same two least significant digits.

### DETAILED DESCRIPTION

Description of Apparatus

The Transversely-Excited Film Bulk Acoustic Resonator (XBAR) is a new resonator structure for use in microwave filters. The XBAR is described in U.S. Pat. No. 10,491,291, titled TRANSVERSELY EXCITED FILM BULK ACOUSTIC RESONATOR, which is incorporated herein by reference in its entirety. An XBAR resonator comprises a conductor pattern having an interdigital transducer (IDT) formed on a thin floating layer or diaphragm of a piezoelectric material. The IDT has two busbars which are each attached to a set of fingers and the two sets of fingers are interleaved on the diaphragm over a cavity formed in a substrate upon which the resonator is mounted. The diaphragm spans the cavity and may include front-side and/or back-side dielectric layers. A microwave signal applied to the IDT excites a shear primary acoustic wave in the piezoelectric diaphragm, such that the acoustic energy flows substantially normal to the surfaces of the layer, which is orthogonal or transverse to the direction of the electric field generated by the IDT. XBAR resonators provide very high electromechanical coupling and high frequency capability.

A piezoelectric membrane may be a part of a plate of single-crystal piezoelectric material that spans a cavity in the substrate. A piezoelectric diaphragm may be the membrane and may include the front-side and/or back-side dielectric layers. An XBAR resonator may be such a diaphragm or membrane with an interdigital transducer (IDT) formed on a diaphragm or membrane. Contact pads can be formed at selected locations over the surface of the substrate to provide electrical connections between the IDT and contact bumps to be attached to or formed on the contact pads.

XBAR fabrication processes may be divided into two broad categories known as “the front-side etch option” and the “backside etch option”. With the front-side etch option, the piezoelectric plate is attached to a substrate and the active portion of the piezoelectric plate floats over a cavity (the “swimming pool”) formed by etching away a tub (e.g., a thickness of an area like a bathtub) of the sacrificial material using an etchant introduced through holes in the piezoelectric plate. With the backside etch option, the piezoelectric plate is attached to a substrate and the active portion of the piezoelectric plate floats over a void etched completely through an area of the substrate and the sacrificial tub from the back side (i.e., the side opposite the piezoelectric plate). The void forms a cavity under the plate.

Currently XBARs are fabricated by laminating a thin piezoelectric plate to a silicon substrate, typically with an oxide interlayer or bonding layer. This can result is stress in the piezoelectric plate due to the substantial thermal coefficient of expansion (TCE) mismatch between the piezoelectric plate and the silicon substrate.

The following describes improved XBAR resonators, filters and fabrication techniques for XBAR resonators that are fabricated using a piezoelectric plate, silicon substrate and handle wafer sandwich, such as by bonding one side of the silicon substrate to a piezoelectric substrate and the other side to the handle wafer having a TCE closer to a TCE of the piezoelectric substrate than the TCE of the silicon substrate, then thinning the piezoelectric substrate to form a piezoelectric plate that allows a frontside membrane release of the plate when forming a cavity under the plate. This can be done by bonding the front surface of the silicon substrate having a filled and planarized sacrificial tub to a piezoelectric substrate and thinning the silicon substrate by removing material from a back surface. Then bonding that back surface to a handle wafer having a thermal coefficient of expansion (TCE) within 2 percent of a TCE of the piezoelectric substrate and thinning the piezoelectric substrate to a target piezoelectric membrane thickness to form a piezoelectric plate. A conductor pattern is formed on the thinned piezoelectric plate and the sacrificial tub is removed to form a cavity and release a membrane of the piezoelectric plate using an etchant introduced through holes in the piezoelectric plate.

Bonding a handle wafer having a TCE closer to a TCE of the piezoelectric substrate or plate than the TCE of the silicon substrate to the back of the silicon substrate makes the overall thermal expansion of the sandwich at some process temperatures closer to that of the plate membrane, and therefore reduces stress in the piezoelectric plate due to the TCE mismatch between the membrane and the silicon substrate. Reduced stress is due to a lower TCE mismatch between the plate and the sandwich having the handle wafer, as compared to between the plate and the substrate alone. In other resonators, the membrane with high stress may become deformed and thus not be not as reliable or perform as well. Thus, a reduced stress in the membrane improves the reliability and performance of the XBARS having the sandwich described herein.

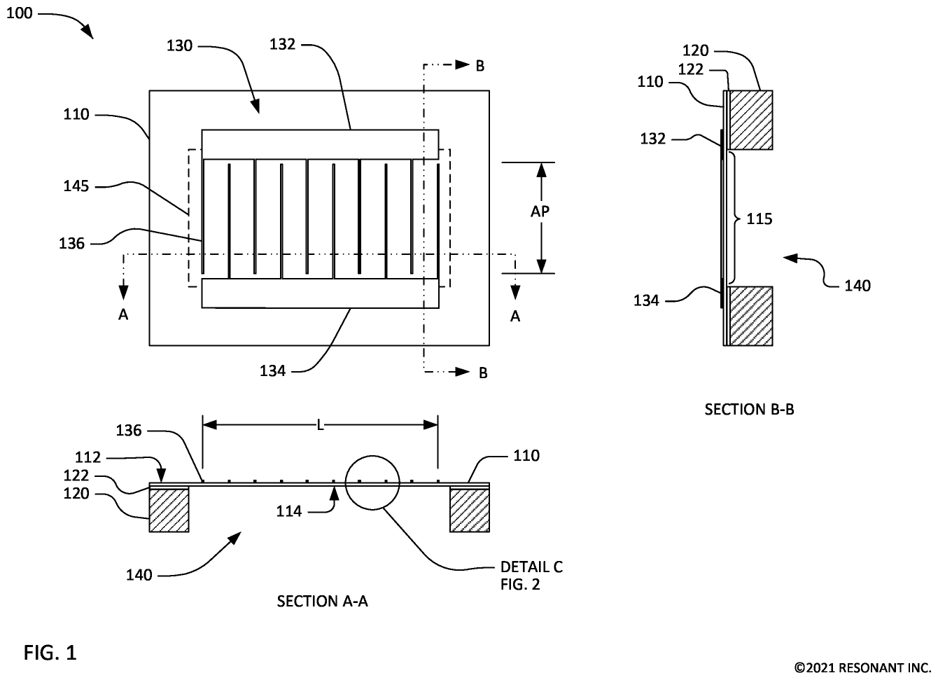

FIG. 1 shows a simplified schematic top view and orthogonal cross-sectional views of a transversely-excited film bulk acoustic resonator (XBAR) 100. XBAR resonators such as the resonator 100 may be used in a variety of RF filters including band-reject filters, band-pass filters, duplexers, and multiplexers. XBARs are particularly suited for use in filters for communications bands with frequencies above 3 GHz.

The XBAR 100 is made up of a thin film conductor pattern formed on a surface of a piezoelectric plate 110 having parallel front and back surfaces 112, 114, respectively. The piezoelectric plate is a thin single-crystal layer of a piezoelectric material such as lithium niobate, lithium tantalate, lanthanum gallium silicate, gallium nitride, or aluminum nitride. The piezoelectric plate is cut such that the orientation of the X, Y, and Z crystalline axes with respect to the front and back surfaces is known and consistent. In the examples presented, the piezoelectric plates may be Z-cut, which is to say the Z axis is normal to the surfaces. However, XBARs may be fabricated on piezoelectric plates with other crystallographic orientations.

The back surface 114 of the piezoelectric plate 110 is attached to a substrate 120 that provides mechanical support to the piezoelectric plate 110. The substrate 120 may be, for example, silicon, sapphire, quartz, or some other material. The substrate may have layers of silicon thermal oxide (TOX) and crystalline silicon. The back surface 114 of the piezoelectric plate 110 may be bonded to the substrate 120 using a wafer bonding process, or grown on the substrate 120, or attached to the substrate in some other manner. The piezoelectric plate is attached directly to the substrate or may be attached to the substrate via a bonding oxide layer 122, such as a bonding oxide (BOX) layer of SiO2, or another oxide such as Al2O3. The substrate 120 may have as its back layer or be bonded to a handle wafer, such as wafer 324.

As shown in FIG. 1, the diaphragm 115 is contiguous with the rest of the piezoelectric plate 110 around all of a perimeter 145 of the cavity 1. In this context, “contiguous” means “continuously connected without any intervening item”. However, it is possible for a bonding oxide layer (BOX) to bond the plate 110 to the substrate 120. The BOX layer may exist between the plate and substrate around perimeter 145 and may extend further away from the cavity than just within the perimeter itself. In the absence of a process to remove it the BOX is everywhere between the piezoelectric plate and the substrate, including as part of the diaphragm 115 over the cavity. In other cases, the BOX may be removed from the back of the diaphragm 115 as part of forming the cavity.

The conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved. The interleaved fingers 136 overlap for a distance AP, commonly referred to as the “aperture” of the IDT. The center-to-center distance L between the outermost fingers of the IDT 130 is the “length” of the IDT.

The first and second busbars 132, 134 serve as the terminals or electrodes of the XBAR 100. A radio frequency or microwave signal applied between the two busbars 132, 134 of the IDT 130 excites a primary acoustic mode within the piezoelectric plate 110. As will be discussed in further detail, the excited primary acoustic mode is a bulk shear mode where acoustic energy propagates along a direction substantially orthogonal to the surface of the piezoelectric plate 110, which is also normal, or transverse, to the direction of the electric field created by the IDT fingers. Thus, the XBAR is considered a transversely-excited film bulk wave resonator.

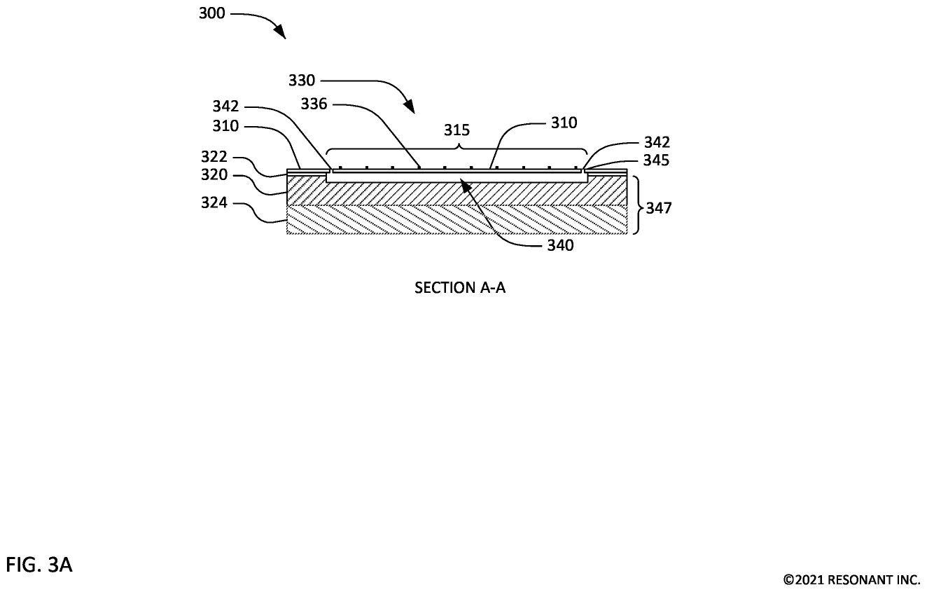

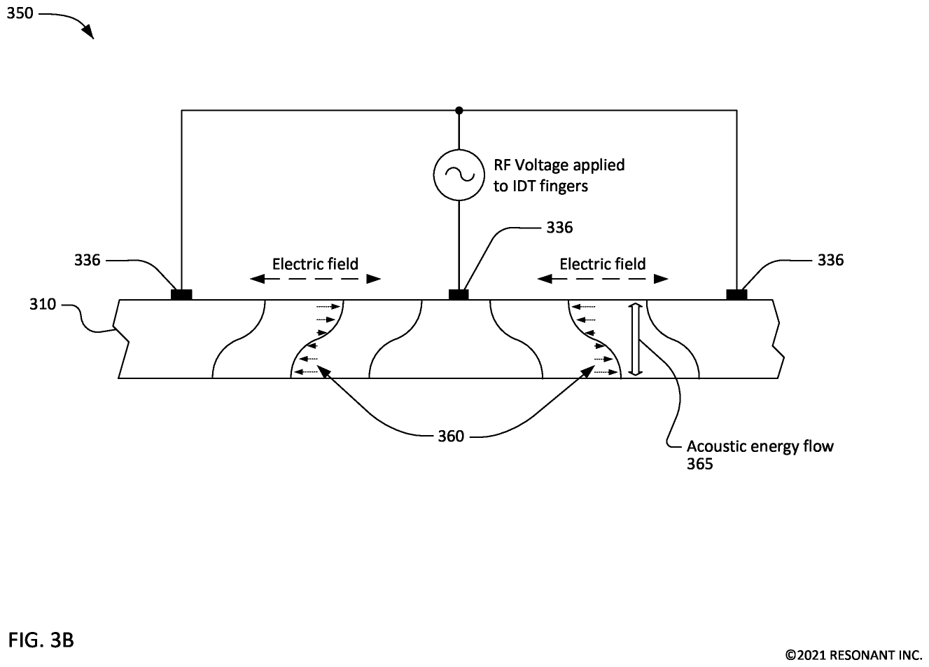

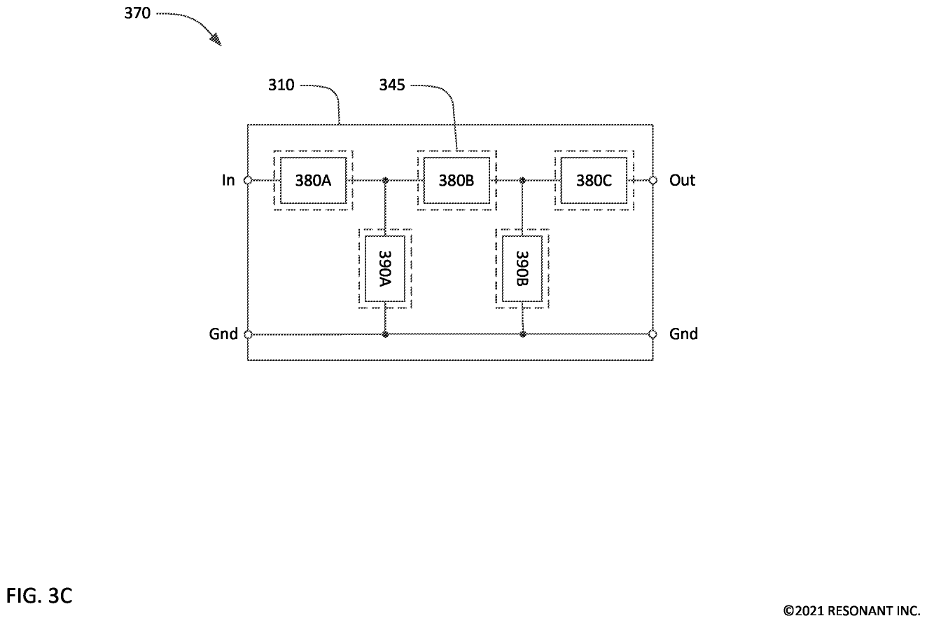

A cavity 140 is formed in the substrate 120 such that a portion 115 of the piezoelectric plate 110 containing the IDT 130 is suspended over the cavity 140 without contacting the substrate 120 or the bottom of the cavity. “Cavity” has its conventional meaning of “an empty space within a solid body.” The cavity may contain a gas, air, or a vacuum. In some case, there is also a second substrate, package or other material having a cavity (not shown) above the plate 110, which may be a mirror image of substrate 120 and cavity 140. The cavity above plate 110 may have an empty space depth greater than that of cavity 140. The fingers extend over (and part of the busbars may optionally extend over) the cavity (or between the cavities). The cavity 140 may be a hole completely through the substrate 120 (as shown in Section A-A and Section B-B of FIG. 1) or a recess in the substrate 120 (as shown subsequently by cavity 340 in FIG. 3A). The cavity 140 may be formed, for example, by selective etching of the substrate 120 before or after the piezoelectric plate 110 and the substrate 120 are attached. In other cases, the cavity is formed by etching a sacrificial layer or tub of material (not shown) formed in the substrate, such as by selectively etching the sacrificial material without etching the substrate or an etch stop material (not shown) in the substrate and surrounding the cavity. As shown in FIG. 1, the cavity 140 has a rectangular shape with an extent greater than the aperture AP and length L of the IDT 130. A cavity of an XBAR may have a different shape, such as a regular or irregular polygon. The cavity of an XBAR may more or fewer than four sides, which may be straight or curved.

The portion 115 of the piezoelectric plate suspended over the cavity 140 will be referred to herein as the “diaphragm” (for lack of a better term) due to its physical resemblance to the diaphragm of a microphone. The diaphragm may be continuously and seamlessly connected to the rest of the piezoelectric plate 110 around all, or nearly all, of perimeter of the cavity 140. In this context, “contiguous” means “continuously connected without any intervening item”. In some cases, a BOX layer may bond the plate 110 to the substrate 120 around the perimeter.

For ease of presentation in FIG. 1, the geometric pitch and width of the IDT fingers is greatly exaggerated with respect to the length (dimension L) and aperture (dimension AP) of the XBAR. A typical XBAR has more than ten parallel fingers in the IDT 110. An XBAR may have hundreds, possibly thousands, of parallel fingers in the IDT 110. Similarly, the thickness of the fingers in the cross-sectional views is greatly exaggerated.

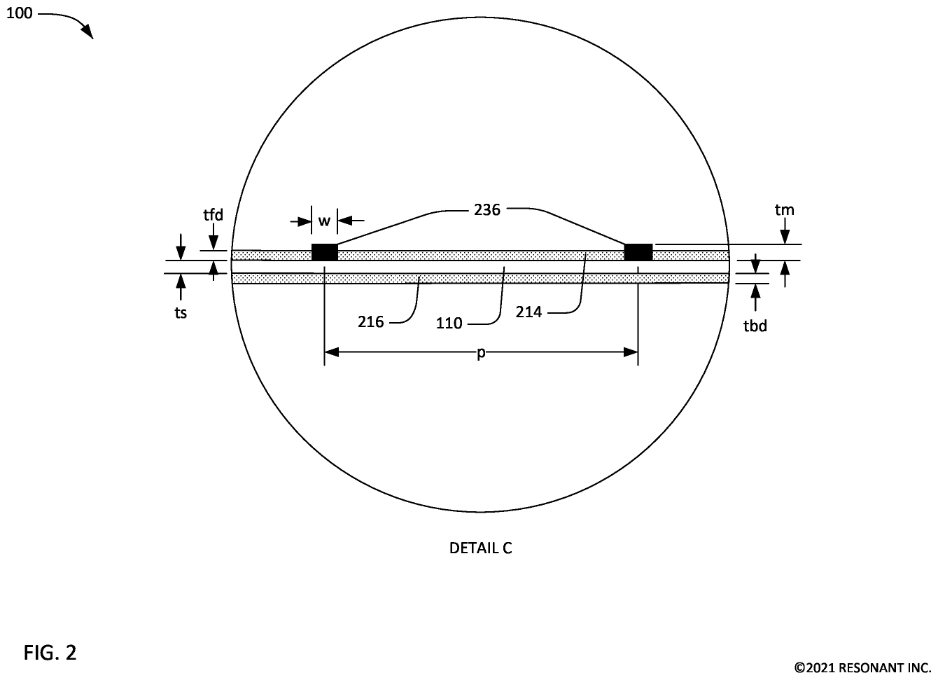

FIG. 2 shows a detailed schematic cross-sectional view of the XBAR 100 of FIG. 1. The cross-sectional view may be a portion of the XBAR 100 that includes fingers of the IDT. The piezoelectric plate 110 is a single-crystal layer of piezoelectrical material having a thickness ts. The ts may be, for example, 100 nm to 1500 nm. It may be between 100 nm and 1000 nm. When used in filters for LTE™ bands from 3.4 GHZ to 6 GHz (e.g., bands 42, 43, 46), the thickness ts may be, for example, 200 nm to 1000 nm.

A front-side dielectric layer 214 may optionally be formed on the front side of the piezoelectric plate 110. The “front side” of the XBAR is, by definition, the surface facing away from the substrate. The front-side dielectric layer 214 has a thickness tfd. The front-side dielectric layer 214 is formed between the IDT fingers 236. Although not shown in FIG. 2, the front side dielectric layer 214 may also be deposited over the IDT fingers 236. A back-side dielectric layer 216 may optionally be formed on the back side of the piezoelectric plate 110. The back-side dielectric layer may be or include the BOX layer. The back-side dielectric layer 216 has a thickness tbd. The front-side and back-side dielectric layers 214, 216 may be a non-piezoelectric dielectric material, such as silicon dioxide or silicon nitride. The tfd and tbd may be, for example, 0 to 500 nm. tfd and tbd are typically less than the thickness ts of the piezoelectric plate. The tfd and tbd are not necessarily equal, and the front-side and back-side dielectric layers 214, 216 are not necessarily the same material. Either or both of the front-side and back-side dielectric layers 214, 216 may be formed of multiple layers of two or more materials.

The front side dielectric layer 214 may be formed over the IDTs of some (e.g., selected ones) of the XBAR devices in a filter. The front side dielectric 214 may be formed between and cover the IDT finger of some XBAR devices but not be formed on other XBAR devices. For example, a front side frequency-setting dielectric layer may be formed over the IDTs of shunt resonators to lower the resonance frequencies of the shunt resonators with respect to the resonance frequencies of series resonators, which have thinner or no front side dielectric. Some filters may include two or more different thicknesses of front side dielectric over various resonators. The resonance frequency of the resonators can be set thus “tuning” the resonator, at least in part, by selecting a thicknesses of the front side dielectric.

Further, a passivation layer may be formed over the entire surface of the XBAR device 100 except for contact pads where electric connections are made to circuitry external to the XBAR device. The passivation layer is a thin dielectric layer intended to seal and protect the surfaces of the XBAR device while the XBAR device is incorporated into a package. The front side dielectric layer and/or the passivation layer may be, SiO₂, Si₃N₄, Al₂O₃, some other dielectric material, or a combination of these materials.

The thickness of the passivation layer may be selected to protect the piezoelectric plate and the metal conductors from water and chemical corrosion, particularly for power durability purposes. It may range from 10 to 100 nm. The passivation material may consist of multiple oxide and/or nitride coatings such as SiO2 and Si3N4 material.

The IDT fingers 236 may be one or more layers of aluminum or a substantially aluminum alloy, copper or a substantially copper alloy, beryllium, tungsten, molybdenum, gold, or some other conductive material. Thin (relative to the total thickness of the conductors) layers of other metals, such as chromium or titanium, may be formed under and/or over the fingers to improve adhesion between the fingers and the piezoelectric plate 110 and/or to passivate or encapsulate the fingers. The busbars (132, 134 in FIG. 1) of the IDT may be made of the same or different materials as the fingers.

Dimension p is the center-to-center spacing or “pitch” of the IDT fingers, which may be referred to as the pitch of the IDT and/or the pitch of the XBAR. Dimension w is the width or “mark” of the IDT fingers. The IDT of an XBAR differs substantially from the IDTs used in surface acoustic wave (SAW) resonators. In a SAW resonator, the pitch of the IDT is one-half of the acoustic wavelength at the resonance frequency. Additionally, the mark-to-pitch ratio of a SAW resonator IDT is typically close to 0.5 (i.e. the mark or finger width is about one-fourth of the acoustic wavelength at resonance). In an XBAR, the pitch p of the IDT is typically 2 to 20 times the width w of the fingers. In addition, the pitch p of the IDT is typically 2 to 20 times the thickness is of the piezoelectric slab 212. The width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w. The thickness of the busbars (132, 134 in FIG. 1) of the IDT may be the same as, or greater than, the thickness tm of the IDT fingers.

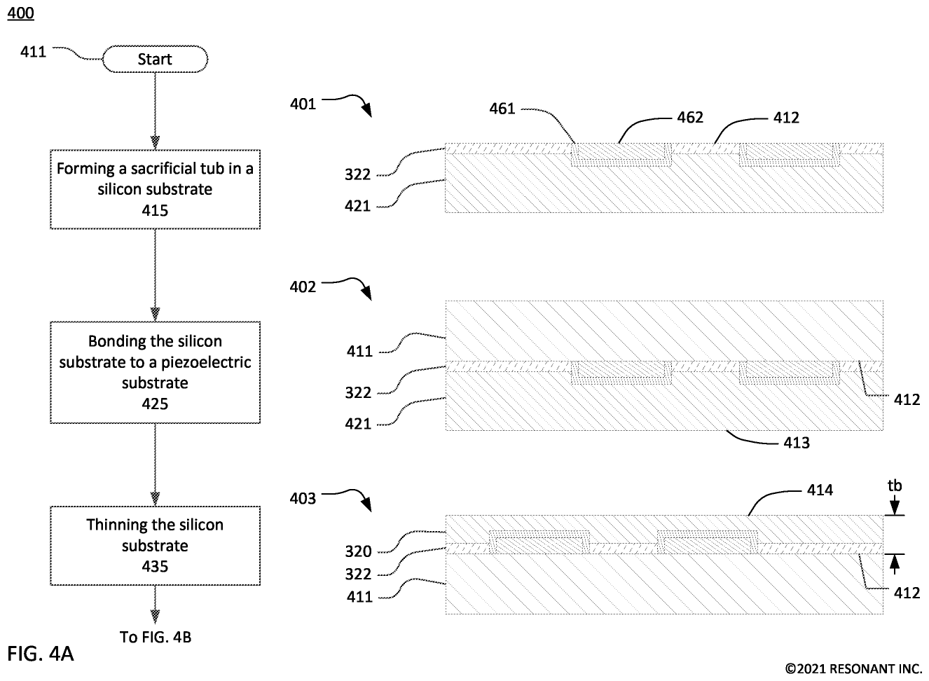

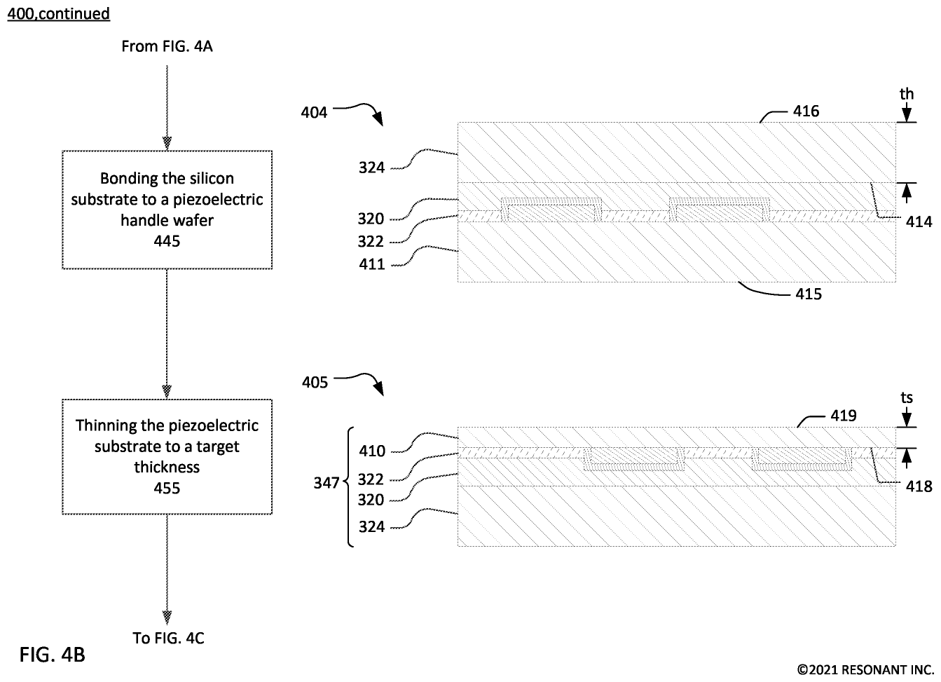

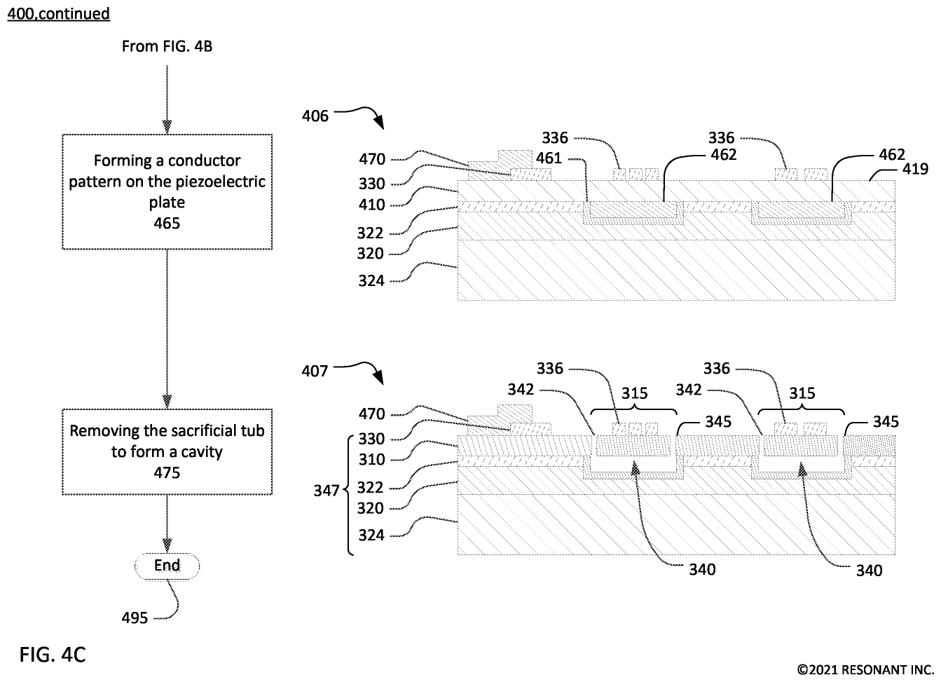

FIG. 3A is an alternative cross-sectional view of XBAR device 300 along the section plane A-A defined in FIG. 1. In FIG. 3A, a piezoelectric plate 310 is attached to a substrate 320. A portion of the piezoelectric plate 310 forms a diaphragm 315 spanning a cavity 340 in the substrate. The cavity 340, does not fully penetrate the substrate 320, and is formed in the substrate under the portion of the piezoelectric plate 310 containing at least fingers 336 the IDT 330 of an XBAR. Fingers, such as finger 336, of an IDT 330 are disposed on the diaphragm 315. Plate 310, diaphragm 315, layer 322, IDT 330 and fingers 336 may be plate 110, diaphragm 115, layer 122, IDT 130 and fingers 136. The cavity 340 may be formed, for example, by etching the substrate 320 before attaching the piezoelectric plate 310. Alternatively, the cavity 340 may be formed by etching the substrate 320 with a selective etchant that reaches the substrate through one or more openings 342 provided in the piezoelectric plate 310. The diaphragm 315 may be contiguous with the rest of the piezoelectric plate 310 around a large portion of a perimeter 345 of the cavity 340. For example, the diaphragm 315 may be contiguous with the rest of the piezoelectric plate 310 around at least 50% of the perimeter of the cavity 340. The cavity 340 may be formed by etching a sacrificial layer or tub of material (not shown) formed in the substrate 320, such as by selectively etching the sacrificial material without etching the substrate 320. In some case, the sacrificial tub is surrounded by an etch stop material (not shown) in the substrate and surrounding the cavity. The etch stop may have an inside surface forming perimeter 345. The etch stop may be thin layer (e.g., see etch stop 461 of FIG. 4) or other layer of material.

One or more intermediate material layers 322 may be attached between plate 310 and substrate 320. An intermediary layer may be or include a bonding layer, a BOX layer, an etch stop layer, a sealing layer, an adhesive layer or layer of other material that is attached or bonded to plate 310 and substrate 320. Layers 322 may be one or more of any of these layers or a combination of these layers.

While the cavity 340 is shown in cross-section, it should be understood that the lateral extent of the cavity is a continuous closed band area of substrate 320 that surrounds and defines the size of the cavity 340 in the direction normal to the plane of the drawing. The lateral (i.e. left-right as shown in the figure) extent of the cavity 340 is defined by the lateral edges substrate 320. The vertical (i.e., down from plate 310 as shown in the figure) extent or depth of the cavity 340 into substrate 320. In this case, the cavity 340 has a side cross-section rectangular, or nearly rectangular, cross section.

The XBAR 300 shown in FIG. 3A will be referred to herein as a “front-side etch” configuration since the cavity 340 is etched from the front side of the substrate 320 (before or after attaching the piezoelectric plate 310). The XBAR 100 of FIG. 1 will be referred to herein as a “back-side etch” configuration since the cavity 140 is etched from the back side of the substrate 120 after attaching the piezoelectric plate 110. The XBAR 300 shows one or more openings 342 in the piezoelectric plate 310 at the left and right sides of the cavity 340. However, in some cases openings 342 in the piezoelectric plate 310 are only at the left or right side of the cavity 340.

The substrate 320 has as its back layer or has its back surface bonded to a handle wafer 324. Handle wafer 324 may be wafer-to-wafer bonded to substrate 320. Handle wafer 324 has a thermal coefficient of expansion (TCE) closer to a TCE of the piezoelectric plate 310 than the TCE of substrate 320 is close to the TCE of the plate 310. In some cases, the TCE of the wafer 324 has a TCE value (e.g., 10−6 m/(m C)) that is closer to a TCE value of the piezoelectric plate 310 than a TCE value of the silicon substrate over a temperature range for fabrication and use of device 300, 370 and/or 407. The wafer 324 having a TCE closer to a TCE of the piezoelectric plate 310 than a TCE of the silicon substrate 320 is having a TCE in a range between the TCE of the silicon substrate 320 and the TCE of the piezoelectric plate 310. It may be 25 percent closer, 50 percent closer or 75 percent closer in that range. It may be 50 percent closer in the range. In some cases, it is 90 percent closer in that range. The wafer 324 may have a TCE nearly equal to the plate 310 which is having a TCE within either five percent or ten percent of the TCE of the plate. In one case, the TCE of the wafer 324 is equal to a TCE of the piezoelectric plate 310, such as where those are the same material.

The handle wafer 324 may be a piezoelectric material as described for plate 110 and/or 310. It may be the same material as the plate. In other cases, it is a different piezoelectric material than that of the plate. The handle wafer 324 can be a non-piezoelectric material that more closely match the TCE of the piezoelectric substrate than the TCE of the silicon substrate. It can be an inexpensive glass material. It can be phosphosilicate glass (PSG) or spin-on glass (SOG). It can be any dielectric material with a CTE closer to that of the piezoelectric plate than the TCE of the silicon substrate.

Each of plate 310, substrate 320 and/or handle wafer 324 can be a substrate or wafer that is as wide as an entire circular processing wafer of material or a portion thereof. They may each have a surface area and thickness to support an XBAR (e.g., XBAR 100 or 300) or an XBAR filter having multiple XBARs (e.g., filter 370).

Thus, XBAR 300 is a transversely-excited film bulk acoustic resonator fabrication using a piezoelectric plate 310, silicon substrate 320 and handle wafer 324 to form sandwich 347. Sandwich 347 may be a substrate formed by the layers of material of plate 310, substrate 320 and wafer 324. In some case, plate 310 is LN, substrate 320 is Si and wafer 324 is LN.

Having the sandwich 347 of layers with wafer 324 having a TCE closer to a TCE of the piezoelectric plate 310 than a TCE of the silicon substrate reduces XBAR membrane deformation and stress due to the TCE difference (e.g., mismatch) between the piezoelectric plate and the silicon substrate because the sandwich 347 includes the wafer 324 with the TCE of the handle wafer that more closely matches the plate. The material and thickness of wafer 324 may be selected to minimize the stress in the plate 310 due to the TCE difference between the piezoelectric plate 310 and the substrate 320. In some cases, the material and thickness of wafer 324 are selected to minimize the TCE difference between the piezoelectric plate 310 and the sandwich 347 with the closer matching TCE of the handle wafer.

FIG. 3B is a graphical illustration of the primary acoustic mode of interest in an XBAR. FIG. 3B shows a small portion of an XBAR 350 including a piezoelectric plate 310 and three interleaved IDT fingers 336. XBAR 350 may be part of any XBAR herein. An RF voltage is applied to the interleaved fingers 336. This voltage creates a time-varying electric field between the fingers. The direction of the electric field is primarily lateral, or parallel to the surface of the piezoelectric plate 310, as indicated by the arrows labeled “electric field”. Due to the high dielectric constant of the piezoelectric plate, the electric field is highly concentrated in the plate relative to the air. The lateral electric field introduces shear deformation, and thus strongly excites a primary shear-mode acoustic mode, in the piezoelectric plate 310. In this context, “shear deformation” is defined as deformation in which parallel planes in a material remain parallel and maintain a constant distance while translating relative to each other. A “shear acoustic mode” is defined as an acoustic vibration mode in a medium that results in shear deformation of the medium. The shear deformations in the XBAR 350 are represented by the curves 360, with the adjacent small arrows providing a schematic indication of the direction and magnitude of atomic motion. The degree of atomic motion, as well as the thickness of the piezoelectric plate 310, have been greatly exaggerated for ease of visualization. While the atomic motions are predominantly lateral (i.e. horizontal as shown in FIG. 3B), the direction of acoustic energy flow of the excited primary shear acoustic mode is substantially orthogonal to the front and back surface of the piezoelectric plate, as indicated by the arrow 365.

An acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. The piezoelectric coupling for shear wave XBAR resonances can be high (>20%) compared to other acoustic resonators. High piezoelectric coupling enables the design and implementation of microwave and millimeter-wave filters with appreciable bandwidth.

FIG. 3C is a schematic circuit diagram and layout for a high frequency band-pass filter 370 using XBARs. The filter 370 has a conventional ladder filter architecture including three series resonators 380A, 380B, 380C and two shunt resonators 390A, 390B. The three series resonators 380A, 380B, and 380C are connected in series between a first port and a second port. In FIG. 3C, the first and second ports are labeled “In” and “Out”, respectively. However, the filter 370 is bidirectional and either port and serve as the input or output of the filter. The two shunt resonators 390A, 390B are connected from nodes between the series resonators to ground. All the shunt resonators and series resonators are XBARs on a single die.

The three series resonators 380A, B, C and the two shunt resonators 390A, B of the filter 370 are formed on a single plate 310 of piezoelectric material bonded to a silicon substrate (not visible). Each resonator includes a respective IDT (not shown), with at least the fingers of the IDT disposed over a cavity in the substrate. In this and similar contexts, the term “respective” means “relating things each to each”, which is to say with a one-to-one correspondence. In FIG. 3C, the cavities are illustrated schematically as the dashed rectangles (such as the rectangle 345). In this example, each IDT is disposed over a respective cavity. In other filters, the IDTs of two or more resonators may be disposed over a single cavity.

Description of Methods

FIGS. 4A, 4B and 4C (collectively “FIG. 4”) are a flow chart 400 of a process for fabricating an improved XBAR or an improved filter incorporating XBARs using a piezoelectric plate, silicon substrate and handle wafer sandwich. The process 400 includes bonding one side of the silicon substrate to a piezoelectric substrate and the other side to the handle wafer having a TCE closer to a TCE of the piezoelectric substrate than a TCE of the silicon substrate, then thinning the piezoelectric substrate to form a piezoelectric plate that allows a frontside membrane release of the plate when forming a cavity under the plate. The process 400 starts at 415. The process 400 ends at 495 with a completed XBAR or filter 407. The process 400 may be or may be included in the forming of XBAR 300, 350 and/or of filter 370. The process may be repeated to form a number of XBARs or filters. It may be repeated to form series XBARS on certain areas of a wafer and repeated to form shunt XBARS on other areas of the wafer. Parts of process 400 may be used to form the series and shunt XBARS. These XBARS may be connected on the wafer to form a filter such as filter 370. The flow chart of FIG. 4 includes only major process steps. Various conventional process steps (e.g. surface preparation, chemical mechanical processing (CMP), cleaning, inspection, deposition, photolithography, baking, annealing, monitoring, testing, etc.) may be performed before, between, after, and during the steps shown in FIG. 4.

The process 400 starts at 415 with forming a filled and planarized sacrificial tub 462 in a front surface of a silicon substrate 421 to create device 401. Substrate 421 is shown with BOX layer 322 and forming tub 462 includes forming a filled and planarized sacrificial tub through a front surface 412 of BOX layer 322 and into silicon substrate 452. Optionally, BOX layer 322 is not present as previously noted; and sacrificial tub 462 is filled and planarized in a front surface silicon substrate 421. In some cases, instead of forming device 401, step 415 is obtaining or receiving device 401, such as by being obtained or purchased from an outside source.

Silicon substrate 421 can be a material as noted for substrate 120, substrate 320 and/or a semiconductor substrate of a semiconductor material other than silicon.

Substrate 421 is shown with etch stop 461, such as a layer of an etch stop material that surrounds the tub 462 or a three dimensional shape of an etch stop material in the substrate for etching cavity 340. Tubs 462 may have a cross-sectional shape (normal to the plane of the drawing) that is a rectangle, a regular or irregular polygon, oval, or some other shape desired for etching through to form cavity 340. The etch stop 461 may have an inside surface forming perimeter 345. Suitable etch-stop materials for etch stop 461 include silicon dioxide, silicon nitride, and aluminum oxide.

The sacrificial material of tub 462 can be any material that can be subsequently removed by selectively etching, dissolving, or some other process that removes tub 462 with respect to the material of etch stop 461 or substrate 320 (if stop 461 does not exist). The sacrificial tub 462 may be silicon nitride, Si₃N₄. In this case, the tub 462 may be etched with phosphoric acid (H3PO4). In another case, the sacrificial tub 462 may be phosphosilicate glass (PSG) that can be etched with vapor Hydrogen Fluoride (HF) or an etchant mixture of carboxylic acid, hydrogen fluoride, and water. In a third case, the sacrificial tub 462 may be spin-on glass (SOG) that can be etched with HF acid.

Etch stop 461 can be etch selective to the sacrificial material. In some cases, sacrificial material 462 is a Silicon type (amorphous silicon, polysilicon etc) within an SiO2 etch stop layer 461. In other cases, sacrificial material 462 is SiN within an SiO2 etch stop layer 461. Alternatively, sacrificial material 462 is SiO2 within a SiN etch stop layer 461. It is also considered that sacrificial material 462 is SiO2 or SiN within an Al2O3 etch stop layer 461. Other embodiments may use a sacrificial material 462 of any of the materials noted but without etch stop 461. For example, sacrificial material 462 may be SiO2 implemented within a Silicon wafer without an etch stop 461.

Device 401 may be formed by patterning the BOX layer and etching a recess for the cavity through the BOX layer a thickness of the substrate. When the BOX layer is not present, the substrate is patterned and etched to form the recess. The recess may be filled with the etch stop material 461 and then sacrificial tub material, which are then planarized to form etch stop 461 and tub 462. If the etch stop 461 does not exist, the recess is only filled with tub material which is then planarized. Filling the recess may be forming a blanket layer of sacrificial material in the recess and over the top of the BOX layer; and planarizing may be performed by mechanical polishing, by chemical-mechanical polishing (CMP), or some other method that removes the top of the filled material until the top surface of the BOX is exposed.

After 415, at 425 the front surface of the silicon substrate is bonded to a piezoelectric substrate 411 to create device 402. Device 402 is shown with front surface 412 of BOX layer 322 bonded to substrate 411. If, BOX layer 322 is not present as previously noted, the top surface of the substrate 421 is directly bonded to the substrate 411. The exposed area of etch stop 461 and tub 462 may also be bonded to substrate 411. The plate substrate may be bonded to the BOX layer 322 and optionally to the etch stop 461 and tub 462 by chemical, atomic and/or adhesive bonding.

The piezoelectric substrate 411 may be a material noted for plate 110 and/or 310. The piezoelectric substrate may be, for example, Z-cut, rotated Z-cut, or rotated Y-cut lithium niobate or lithium tantalate. The piezoelectric substrate may be some other material and/or some other cut as previously noted for plate 110. The substrate may be an LiNbO3 (LN) substrate having a thickness between 150 um and 350 um. It may have a thickness of 250 um.

The piezoelectric substrate 411 may be bonded to the BOX and silicon substrate using a wafer-to-wafer bonding process that bonds opposed mating surfaces of two processing wafers.

At 435 the silicon substrate 421 is thinned by removing material from a back surface of the substrate 421 to form silicon substrate 320 having back surface 414 and device 403. Thinning at 435 may be performed by planarizing, by mechanical polishing, by chemical-mechanical polishing (CMP), or some other method. In some cases, thinning is a timed planarizing until the material of substrate 421 has thickness tb. Thus, the silicon substrate 320 may have a thickness tb of between 15 μm and 200 μm thick between its top surface 412 and planarized bottom surface 414. In other cases, substrate 320 may have a thickness tb of between 20 μm and 500 μm thick. Substrate 320 may have a thickness tb of between 30 μm and 675 μm.

Thickness tb may be a thickness selected so that bonding the back surface 414 of the silicon substrate 320 to a handle wafer 324 having a TCE closer to a TCE of the piezoelectric substrate 411 than a TCE of the silicon substrate reduces XBAR membrane deformation and stress by minimizing stress in the plate 310 due to the TCE difference between the piezoelectric plate 310 and the substrate 320. Thickness tb may be selected to reduce XBAR membrane deformation and stress in plate 310 of sandwich 347 having substrate 320 bonded to the wafer 324 with the closer matching TCE of the handle wafer.

At 445 the back surface 414 of the thinned silicon substrate 320 is boned to a handle wafer 324 having a TCE closer to a TCE of the piezoelectric substrate 411 than a TCE of the silicon substrate to form device 404. The back surface 414 of the thinned silicon substrate 320 may be directly boned to a top surface of handle wafer 324. In other cases, a bonding layer (not shown) may exist between substrate 320 and wafer 324, such as noted for bonding layer 322. The substrate 320 may be bonded to the wafer 324 by chemical, atomic and/or adhesive bonding.

The handle wafer 324 may be a material noted for substrate 411, plate 110 and/or 310. The handle wafer 324 may be an LiNbO3 (LN) substrate. Wafer 324 may have a thickness th of between 250 um and 1000 μm thick between its top surface 414 and planarized bottom surface 416. In other cases, wafer 324 may have a thickness th of between 100 and 1000 μm thick.

Thickness th may be a thickness selected so that bonding the back surface 414 of the silicon substrate 320 to a handle wafer 324 having a TCE closer to a TCE of the piezoelectric substrate 411 than a TCE of the silicon substrate reduces XBAR membrane deformation and stress by minimizing stress in the plate 310 due to the TCE difference between the piezoelectric plate 310 and the substrate 320. Thickness tb may be selected to reduce XBAR membrane deformation and stress in plate 310 of sandwich 347 having substrate 320 bonded to the wafer 324 with the closer matching TCE of the handle wafer.

The handle wafer 324 may be bonded to the silicon substrate 320 using a wafer-to-wafer bonding process that bonds opposed mating surfaces of two processing wafers.

At 455 the piezoelectric substrate 411 is thinned to a target piezoelectric membrane thickness is to form a piezoelectric plate 410 and device 405. At 455, piezoelectric substrate 411 is thinned into a piezoelectric plate 410 that will become plate 310 holes 342 are formed in plate 410 at 475. At 455 the piezoelectric substrate 411 is thinned by removing material from a front surface 415 of the substrate 411 to form piezoelectric plate 410 having front surface 419 and back surface 418.

Thinning at 455 may be performed by planarizing, by mechanical polishing, by chemical-mechanical polishing (CMP), or some other method. Planarizing the plate may include thinning the plate by ion slicing, CMP or some other method to polish the plate to a desired thickness of plate 410. In some cases, thinning is a timed planarizing until the material of substrate 411 has thickness ts between its planarized front surface 419 and back surface 418. Thickness ts may be as noted herein.

Thinning at 455 may be done using a suitable wet or dry etching process. The thinning may be done by an ion milling, a reactive ion etching (RIE), an inductively coupled plasma (ICP) and/or a laser milling process.

Thus, device 405 has sandwich 347 formed by the layers of piezoelectric plate 410, silicon substrate 320 and handle wafer 324. Having the sandwich 347 of layers with wafer 324 having a TCE closer to a TCE of the piezoelectric plate 410 than a TCE of the silicon substrate reduces XBAR membrane deformation and stress by minimizing stress in the plate 310 due to the TCE mismatch between the piezoelectric plate 410 and the substrate 320 because the sandwich 347 includes the wafer 324 with the closer matching TCE of the handle wafer.

Thickness ts may be a thickness selected so that bonding the back surface 414 of the silicon substrate 320 to a handle wafer 324 having a TCE closer to a TCE of the piezoelectric plate 410 than a TCE of the silicon substrate reduces XBAR membrane deformation and stress by minimizing stress in the plate 310 due to the TCE difference between the piezoelectric plate 310 and the substrate 320. Thickness ts may be selected to reduce XBAR membrane deformation and stress in plate 310 of sandwich 347 having substrate 320 bonded to the wafer 324 with the closer matching TCE of the handle wafer. This selection may be a factor in selecting thickness ts along with other factors for ts explained herein.

At 465 at least one conductor pattern is formed on front surface 419 of the thinned piezoelectric plate 410 to form device 406. Surface 419 is the thinned surface of plate 410 that is away from the handle wafer 324. The conductor pattern includes an IDT 330 having interleaved fingers 336. The conductor pattern may be an M1 metal layer.

A mask may be patterned onto the top surface 419 of plate 410 to form the IDT 330. Forming IDT may include forming conductor patterns and dielectric layers defining one or more XBAR devices on the surface of the piezoelectric plate 410. Typically, a filter device will have an IDT as a first of two or more conductor layers that are sequentially deposited and patterned. The IDT layers may be, for example, aluminum, an aluminum alloy, copper, a copper alloy, molybdenum, tungsten, beryllium, gold, or some other conductive metal. Optionally, one or more layers of other materials may be disposed below (i.e. between the IDT layer and the piezoelectric plate) and/or on top of the IDT. For example, a thin film of titanium, chrome, or other metal may be used to improve the adhesion between the IDT layer and the piezoelectric plate.

The IDT 330 may be formed by depositing the conductor layers over the surface 419 of the piezoelectric plate 410 and removing excess metal by etching through a patterned photoresist that covers areas of the IDT. Alternatively, the IDT may be formed using a lift-off process. Photoresist may be deposited over the piezoelectric plate and patterned to remove areas that leave behind or define the IDT. The IDT material may be deposited in sequence over the surface of the photoresist and piezoelectric plate. The photoresist may then be removed, which removes the excess material, leaving the IDT.

Also, at 465, a second M2 metal layer 470 may be formed on the conductor pattern. Second M2 metal layer 470 is electrically conductive material attached to the top of the M1 layers or IDT, such as to the top of the busbars and not to the top of the fingers 336. In some cases, the second metal layer 470 is multiple conductive layers formed similar to forming the IDT 330.

Layer 470 may include contact pads for connecting to contact bumps. The contact pads may be for electrically contacting contact bumps that are bonding pads, gold or solder bumps, or other means for making connection between the device 407 (e.g., contact pads, conductor layers or busbars) and a package, PCB and/or external circuitry (e.g. see step 495).

The material of layer M1 and layer M2 may be a metal or conductor as described for IDT 130. They may be the same material. They may be a different material. They may be formed during one or more different processing steps. These steps may be different than steps for forming the IDT.

Forming the M1 and M2 layers may include patterning and fabricating those layers separately. In some cases, the plate 410 is Lithium Niobate (LN) which may be 275 nm thick; the BOX 422 is SiO2; the M1 or IDT is Aluminum (Al) metal traces; and the M2 is Gold (Au) contact pads and traces.

At 475 the sacrificial tub 462 is removed to form a cavity 340 under a membrane of the piezoelectric plate 410 to form device 407. Device 407 has diaphragm 315 with perimeter 345 formed where at the edges of cavity 340, or where the inside surface of etch stop 461 contacts plate 310.

Tub 462 may be removed using an etchant introduced through holes 342 in the piezoelectric plate 310. Holes 342 can be formed before, during or after step 465, but before removing tub 462 at step 475. Piezoelectric plate 410 becomes plate 310 when holes 342 are formed in plate 410.

Plate 410 may be masked and holes 342 etched through the plate using a selective or timed etch. Holes 342 are etched through the piezoelectric plate 410 and to sacrificial tub 462. While the holes 342 are only shown in cross-section in the figures, it must be understood that each hole 342 is a three-dimensional opening created by removing material from the plate. Openings 342 may have a cross-sectional shape (normal to the plane of the drawing) that is a rectangle, a regular or irregular polygon, oval, or some other shape desired for etching through to form cavity 340.

The mask may be a photoresist mask or a hard mask, and etching holes 342 may be done using a suitable wet or dry etching process. The holes 342 may be formed using ion milling. In some cases, the etching may be done by an ion milling, a reactive ion etching (RIE), an inductively coupled plasma (ICP) and/or a laser milling process. Other etching processes may be used on the plate to form holes 342.

The cavity 340 may be formed by selectively etching the sacrificial tub 462 without etching the etch stop 461 or substrate 320. Etching at 475 can be selectively etching, dissolving, or some other process that removes all or substantially all of tub 462 without removing any or barely any of the material of etch stop 461. A separate cavity may be formed for each of different types of XBARs such as for each of series and shunt resonators 380 and 390 in device 370.

Cavity 340 may be formed by etching away the sacrificial tub 462 with a selective etchant that etches the sacrificial tub through one or more holes 342 through the piezoelectric plate 310. Etching at 475 may fabricate an XBAR by front side etching the sacrificial tub 462 to form cavity 340 using an isotropic etch. The etch may be a wet or dry etch. Cavity 340 may be formed where the sacrificial but 462 was removed.

Isotropic etching may include using an etchant in liquid-, gas- or plasma-phase. The liquid etchant may be buffered hydrofluoric acid (BHF) such as used for silicon dioxide etching. Unlike anisotropic etching, isotropic etching does not etch in a single direction, but rather etches in multiple directions within the silicon nitride tub. However, isotropic etching has the advantage of being faster than anisotropic etching. Typical etch rates for isotropic etching range from a few microns to several tens of microns per minute, while anisotropic etching generally has an etch rate of about 1 μm/min.

When the sacrificial tub 462 is silicon nitride, Phosphoric etching of the silicon nitride tub (e.g., etching of Si3N4) may include using phosphoric acid (H3PO4) at a temperature of 140-200° C. Typical selectivities in phosphoric etch are 10:1 for nitride over oxide and 30:1 for nitride over Si. When the sacrificial tub 462 is phosphosilicate glass (PSG) the tub may be etched with vapor Hydrogen Fluoride (HF) such as an etchant mixture of carboxylic acid, hydrogen fluoride, and water. When the sacrificial tub 462 is spin-on glass (SOG) the tub may be etched with HF acid.

Thus, cavity 340 is in an area (e.g., within perimeter 345) through BOX layer 322 and a thickness of the substrate 320 to a vertical extent or depth desired for cavity 340. At 475 the sacrificial tub 462 may be selectively etched with respect to a mask (not shown) over device 406, or with respect to the top of device 406.

In some cases, the etch at step 475 is performed by a frontside membrane release (FSMR) technique which is a process to selectively remove the sacrificial tub 462 using a highly selective dry vapor etchant such as Phosphor or HF. This process can be conducted on the device layer side (e.g., a frontside etch) as opposed to the backside release where a through hole needs to be created in the Si substrate and wafer 324 to gain access to the sacrificial material.

Structure 407 has sandwich 347 with plate 310 formed form plate 410 by having holes 342. Sandwich 347 may be the same at steps 455 and 475 because holes 342 do not change the TCE of plate 310 as compared to that of plate 410.

Process 400 may end at 495 with a completed XBAR conductor pattern formed on a released membrane of piezoelectric material plate 310 over each of the cavities 340. The completed XBAR conductor pattern on the plate at 310 may be a conductor pattern that is or that includes the IDT patterns and/or fingers described herein for XBAR devices.

Actions that may occur at 495 include depositing further metal layers and/or bonding device 407 to another device, package or PCB. Actions that occur at 495 may also include forming solder bumps or other means for making connection between the device 407 and external circuitry; excising individual devices from a wafer containing multiple devices; other packaging steps; and testing. Another action that may occur at 495 is to tune the resona8nt frequencies of the resonators within a filter device by adding or removing metal or dielectric material from the front side of the device shown in 407. After the filter device is completed, the process ends at 495. Any number of FIGS. 1-3A may show examples of the XBAR device or resonator after completion at 495.

In some cases, only steps 435-445 and 455 of the process 400 are performed, such as where device 402 is obtained (see step 415 for an example definition of obtained) and device 405 is the output of the process. In other cases, only steps 435 and 445 of the process 400 are performed, such as where device 402 is obtained and device 404 is the output of the process.

In some cases, device 401 does not have the etch stop layer, and the sacrificial tub 462 is selectively etched away at 475 with respect to the BOX layer 322 and the substrate 320. In cases where BOX layer 322 does not exist, the selective etch is with respect to the substrate 320.

In some cases, device 401 does not have the etch stop or the sacrificial tub, and the cavity is etched at 475 through the BOX layer 322 and into the substrate 320 with a timed etch. In cases where BOX layer 322 does not exist, the timed etch is with respect to the substrate 320.

Thus, process 400 forms and XBAR 300 is improved XBAR resonators or filters using fabrication techniques having a piezoelectric plate 310, silicon substrate 320 and handle wafer 324 sandwich 347, where the handle wafer has a TCE closer to a TCE of the piezoelectric substrate than a TCE of the silicon substrate, then thinning the piezoelectric substrate to form a piezoelectric plate that allows a frontside membrane release of the plate when forming a cavity under the plate.

Mismatches between the TCE of plate 310 and a silicon substrate, without wafer 324 affect product reliability and filter performance due to permanent deformation and residual stress in the XBAR membrane (e.g., in diaphragm 315) after process steps caused by thermal mismatch between the plate (e.g., Lithium Niobate) and silicon substrate due to their different thermal expansion coefficients. The embodiments herein minimize the thermal mismatch and thus reduce deformation and stress in the XBAR membrane, and improve performance and reliability of XBAR product by using the sandwich structure 347 in process 400 which where the handle wafer 324 has a TCE closer to a TCE of the piezoelectric plate 310 than a TCE of the silicon substrate.

Bonding a handle wafer 324 having a TCE closer to a TCE of the piezoelectric substrate 411 (or plate 410 or 310) than a TCE of the silicon substrate to the back of the silicon substrate makes the overall thermal expansion of the sandwich 347 at some process temperatures closer to that of the plate membrane, and therefore reduces stress in the plate 310 due to the thermal mismatch between the membrane and the silicon substrate 320 by having sandwich 347 with substrate 320 bonded to the wafer 324.

In other resonators, the membrane buckles to a serpentine shape with high stress associated with deformation at and post processing reflow temperatures. Membranes of the sandwiches 347 herein do not buckle to a serpentine shape during processing due to much less stress associated with the deformation at and post reflow temperatures. A reduced stress in the membrane improves the reliability and performance of the XBARS having the sandwich 347 described herein.

Process 400 also has advantages of a frontside membrane release (FSMR) of the plate 310 from a substrate 320 when forming a cavity 340 under the plate as compared to a backside membrane release (BSMR) process of FIG. 1. BSMR typically uses a deep reactive ion etching (DRIE) technique to remove the Si substrate 120 underneath the piezoelectric plate 110 and the etching time increases with Si substrate thickness. Instead, the technology herein use a FSMR etch processing of step 475 of FIG. 4 which takes less etchant and time.

Also, other FSMR techniques use pre-patterned Si substrates with air cavities below the plate and then require frontside device fabrication of conductor layers on thin plates which poses a high risk due to the fragility of the thin plate as the frontside device fabrication can crack and/or damage the thin plate. The described sandwich structure 347 and process 400 will enable frontside device fabrication on thin piezoelectric plates at 465 prior to etching cavities at 475. The process 400 uses a piezoelectric substrate thinning approach at step 455 that mitigates this cracking risk by providing an underlying support structure of tub 462 for the piezoelectric plate during the device processing as shown. Thus, the frontside processing to form conductor layers and dielectric layers at 465 will not crack and/or damage the thin plate 410 because the handle tub 462 will support the plate 410, instead of the plate being suspended over air or a layer that is not a thick handle wafer.

Closing Comments

Throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

It is claimed:

1. An acoustic resonator device comprising:
a silicon substrate having a back surface and a front surface;
a piezoelectric plate bonded to the front surface of the silicon substrate;
a handle wafer bonded to the back surface of the silicon substrate, the handle wafer having a thermal coefficient of expansion (TCE) closer to a TCE of the piezoelectric substrate than a TCE of the silicon substrate;
at least one conductor pattern formed on the piezoelectric plate; and
a cavity formed under a membrane of the piezoelectric plate.

2. The device of claim 1, wherein the handle wafer has a TCE nearly equal to a TCE of the piezoelectric substrate to reduced stress in the piezoelectric plate due to a thermal coefficient of expansion mismatch between a piezoelectric plate and a silicon substrate.

3. The device of claim 1, wherein the piezoelectric plate, silicon substrate and handle wafer form a substrate sandwich having a reduced stress in the piezoelectric plate due to the TCE mismatch between the piezoelectric plate and the silicon substrate of the sandwich as compared to a stress in the piezoelectric plate of only the piezoelectric plate and the silicon substrate without the handle wafer.

4. The device of claim 1, wherein a thickness is of the piezoelectric plate is between 100 nm and 1500 um, a thickness tb of the silicon substrate is between 15 and 200 um and a thickness th of the handle wafer is between 100 um and 1000 um.

5. The device of claim 1, wherein the front surface of the silicon substrate is wafer-to-wafer bonded to the piezoelectric plate; and
wherein the back surface of the silicon substrate is wafer-to-wafer bonded to the handle wafer.

6. The device of claim 1, wherein the at least one conductor pattern comprises an interdigital transducer (IDT) with interleaved fingers disposed on the membrane to form a diaphragm over a cavity.

7. The device of claim 6, wherein:
the piezoelectric plate and the at least one conductor pattern are configured such that radio frequency signals applied to the conductor pattern excites a primary shear acoustic mode in the piezoelectric plate over the cavity, wherein a thickness of the diaphragm is selected to tune the primary shear acoustic modes in the piezoelectric plate.

8. The device of claim 1, further comprising:
holes formed in the piezoelectric plate for etching through the plate and to the cavity; and
an etch stop layer lining the cavity.

9. The device of claim 1, wherein back surface and the front surface of the silicon substrate are planarized; and
wherein the piezoelectric plate has a target piezoelectric membrane thickness.

10. An acoustic resonator device having reduced stress in a piezoelectric plate, comprising:
a silicon substrate having a back surface and a front surface;
a piezoelectric plate bonded to the front surface of the silicon substrate;
a handle wafer bonded to the back surface of the silicon substrate, the handle wafer having a thermal coefficient of expansion (TCE) 50 percent closer to a TCE of the piezoelectric substrate than a TCE of the silicon substrate;
at least one conductor pattern formed on the piezoelectric plate; and
a cavity formed under a membrane of the piezoelectric plate.

11. The device of claim 10, wherein the handle wafer has a TCE nearly equal to a TCE of the piezoelectric substrate to reduced stress in the piezoelectric plate due to a thermal coefficient of expansion mismatch between a piezoelectric plate and a silicon substrate.

12. The device of claim 10, wherein the piezoelectric plate, silicon substrate and handle wafer form a substrate sandwich having a reduced stress in the piezoelectric plate due to the TCE mismatch between the piezoelectric plate and the silicon substrate of the sandwich as compared to a stress in the piezoelectric plate of only the piezoelectric plate and the silicon substrate without the handle wafer.

13. The device of claim 10, wherein a thickness is of the piezoelectric plate is between 100 nm and 1500 um, a thickness tb of the silicon substrate is between 15 and 200 um and a thickness th of the handle wafer is between 100 um and 1000 um.

14. The device of claim 10, wherein the front surface of the silicon substrate is wafer-to-wafer bonded to the piezoelectric plate; and
wherein the back surface of the silicon substrate is wafer-to-wafer bonded to the handle wafer.

15. The device of claim 10, wherein the at least one conductor pattern comprises an interdigital transducer (IDT) with interleaved fingers disposed on the membrane to form a diaphragm over a cavity.

16. The device of claim 15, wherein:
the piezoelectric plate and the at least one conductor pattern are configured such that radio frequency signals applied to the conductor pattern excites a primary shear acoustic mode in the piezoelectric plate over the cavity, wherein a thickness of the diaphragm is selected to tune the primary shear acoustic modes in the piezoelectric plate.

17. The device of claim 1, further comprising:
holes formed in the piezoelectric plate for etching through the plate and to the cavity; and
an etch stop layer lining the cavity.

18. An acoustic resonator device having reduced stress in a piezoelectric plate, comprising:
a silicon substrate having a back surface and a front surface;
a piezoelectric plate bonded to the front surface of the silicon substrate;
a handle wafer bonded to the back surface of the silicon substrate, the handle wafer having a thermal coefficient of expansion (TCE) nearly equal to a TCE of the piezoelectric substrate than a TCE of the silicon substrate;
at least one conductor pattern formed on the piezoelectric plate; and
a cavity formed under a membrane of the piezoelectric plate.

19. The device of claim 18, wherein the piezoelectric plate, silicon substrate and handle wafer form a substrate sandwich having a reduced stress in the piezoelectric plate due to the TCE mismatch between the piezoelectric plate and the silicon substrate of the sandwich as compared to a stress in the piezoelectric plate of only the piezoelectric plate and the silicon substrate without the handle wafer.

20. The device of claim 18,
wherein the conductor pattern comprises forming an interdigital transducer (IDT) with interleaved fingers disposed on a diaphragm over a cavity; and
wherein the piezoelectric plate and the conductor pattern are configured such that radio frequency signals applied to the conductor pattern excites a primary shear acoustic mode in the piezoelectric plate over the cavity, wherein a thickness of the diaphragm is selected to tune the primary shear acoustic modes in the piezoelectric plate.
